(19) United States
(12) Patent Application Publication
(10) Pub. No.: US 2023/0198524 A1
(43) Pub. Date: Jun. 22, 2023

(54) ZERO STATIC CURRENT HIGH-SPEED VOLTAGE LEVEL SHIFTER

(71) Applicant: SanDisk Technologies LLC, Addison, TX (US)

(72) Inventor: Shiv Harit Mathur, Bangalore (IN)

(21) Appl. No.: 17/553,630

(22) Filed: Dec. 16, 2021

(51) Int. Cl. H03K 19/0175; H03K 3/037; H03K 19/20

(52) U.S. Cl. CPC H03K 19/017509; H03K 3/037; H03K 19/20

(57) ABSTRACT

An improved cross-coupled voltage level shifter is disclosed that is capable of achieving substantially higher data transfer speeds with reduced transistor sizes than existing cross-coupled voltage level shifters. The voltage level shifter includes a cross-coupled latch, control circuitry that initiates a state transition of the latch responsive to activation, where the control circuitry is activated by a change in a logic voltage level of an input signal to the voltage level shifter, and feedback circuitry that reinforces the latch action of the cross-coupled latch. The control circuitry may include pull-down transistors that are thin-gate devices, and thus, substantially smaller in area than what would otherwise be needed to meet the large current requirement of the pull-down transistors as compared to latch transistors of the latch.

### BACKGROUND

A level shifter—also referred to at times as a level translator, a logic-level shifter, a voltage level shifter, or a voltage level translator—is an electronic circuit that translates input signals having voltage logic levels in a first voltage domain to output signals having voltage logic levels in a second voltage domain. Level shifters include step-up level shifters, where one or more voltage logic levels in the first domain are lower than a corresponding one or more voltage logic levels in the second domain, and step-down level shifters, where one or more voltage logic levels in the first domain are higher than a corresponding one or more voltage logic levels in the second domain. Level shifters may be configured in chips or dies having different operational domains and/or interfaces. Level shifters may be used as the building blocks for integrated circuit (IC) design, including those that employ complementary metal-oxide-semiconductor (CMOS) technology. Level shifters may enable compatibility between ICs with different voltage requirements, for example.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIGS. 1A, 1B, and 1C depict a circuit implementation of a cross-coupled voltage level shifter.

FIG. 2 is a block diagram of a zero static current high-speed voltage level shifter according to example embodiments of the disclosed technology.

FIGS. 3A, 3B, and 3C depict a circuit implementation of a zero static current high-speed voltage level shifter according to example embodiments of the disclosed technology.

FIGS. 4A and 4B are flowcharts depicting a method of operation of a zero static current high-speed voltage level shifter according to example embodiments of the disclosed technology.

FIG. 5 is a plot of waveforms of various voltage signals over the course of multiple latch state transitions of a zero static current high-speed voltage level shifter according to example embodiments of the disclosed technology.

FIG. 6 is a schematic block diagram of a system in which a voltage level shifter according to example embodiments of the disclosed technology may be implemented.

The figures are not exhaustive and do not limit the present disclosure to the precise form disclosed.

### DETAILED DESCRIPTION

Level shifters are widely used in IC design to perform voltage level translation. For instance, a level shifter may sit on a data path connecting a first IC and a second IC fabricated on respective dies. To reduce power consumption and increase performance, an operating voltage within an IC's core is typically lower than outside the IC. As such, the lower voltages exiting the first IC may be more susceptible to distortion as they travel along the data path to the second IC due to noise present in the environment between the two ICs. To mitigate the effect of this distortion due to noise, a step-up level shifter may be used to convert voltages leaving the first IC from the lower operating voltage of the first IC, for example 0.7V, to the higher operating voltage of the environment external to the first IC, e.g., 1.2V or 1.8V. More generally, a step-up level shifter may convert input voltages in a first voltage domain to output voltages in a second domain such that at least one voltage in the first domain (e.g., a voltage in the first domain that corresponds to a logic high level) is lower than a corresponding voltage in the second domain (e.g., a voltage in the second domain that corresponds to the logic high level). A step-down level shifter may then be used to convert the voltages prior to entering the second IC from the higher operating voltage of the external environment to the lower core operating voltage of the second IC. More generally, a step-down level shifter may convert input voltages in a first voltage domain to output voltages in a second domain such that at least one voltage in the first domain (e.g., a voltage in the first domain that corresponds to a logic high level) is higher than a corresponding voltage in the second domain (e.g., a voltage in the second domain that corresponds to the logic high level).

As data transmission speeds continue to increase, the need for higher-speed level shifters has become more pressing. Moreover, as described above, because a level shifter may sit along a data path, the penalty or timing budget consumed by a level shifter directly impacts overall device performance. In addition, in order to meet dual port data memory (DPDM) targets, level shifters may be required to consume low static current.

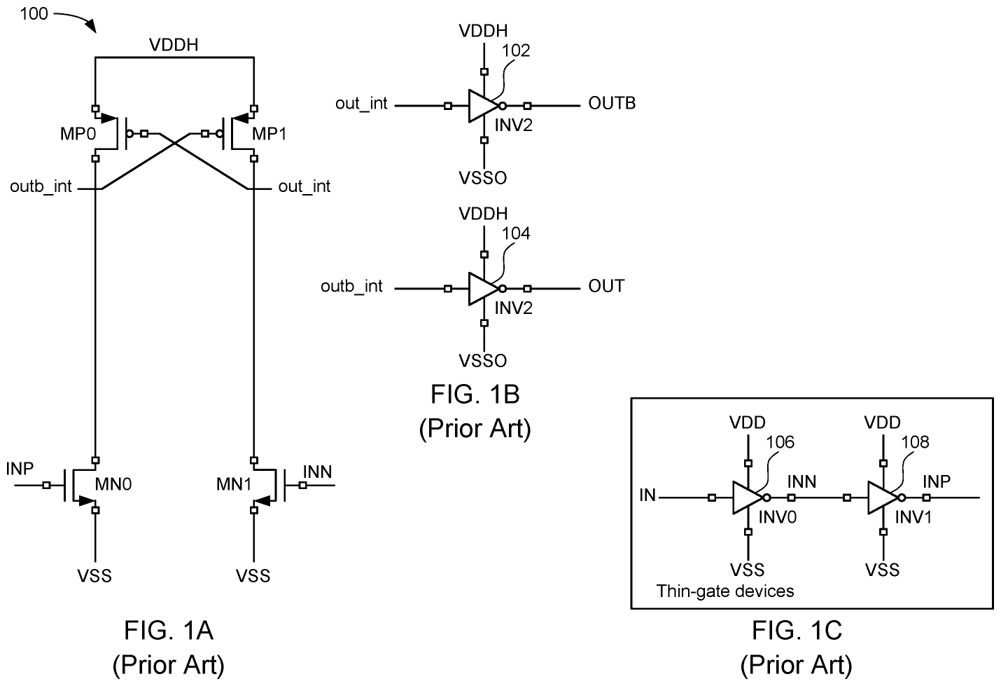

Cross-coupled level shifters, such as those having the example circuit implementation depicted in FIGS. 1A-1C, are used widely across industry to perform signal conversion between a low voltage domain (e.g., 0.7V) and a high voltage domain (e.g., 1.2V). This type of architecture provides high gain during voltage conversion due to the operation of a p-channel metal-oxide-semiconductor (pMOS)-based latch. In addition, this architecture operates according to a “ratioed-logic” whereby the N-to-P device ratio is 2-3 times to enable the voltage conversion and a balanced duty-cycle. However, this existing cross-coupled level shifter architecture suffers from various technical problems, particularly with respect to the level shifter's ability to achieve higher target performance and consume less static current.

N-channel MOS (nMOS) pull-down devices within the existing cross-coupled level shifter design receive input voltages and initiate a state transition for the pMOS-based latch. These nMOS devices have a substantially larger current requirement than the pMOS devices. In particular, the nMOS pull-down devices need to generate enough current to pull-down the voltage at corresponding drain side nodes of the pMOS devices by at least corresponding threshold voltages of the pMOS devices in order to enable the latch action. To meet this larger current requirement, the nMOS devices have a larger area (e.g., 5-10 times larger) than the pMOS devices. Further, as the input voltages to the level shifter are reduced, the width requirements for an nMOS pull-down device increases even further because its threshold voltage Vt does not does generally scale with the operating voltage of the technology employed.

A further technical problem associated with this type of existing cross-coupled level shifter design is that as the size of an nMOS device increases to meet the current requirements associated with increased target speed requirements, the parasitic capacitance at output nodes of the level shifter also increases due to the larger size of the device leading to Miller capacitance between input and output nodes. Thus, while increasing the area of an nMOS device to generate more current through the device at a given input voltage can assist with achieving higher data transfer speeds up to a certain threshold speed, any additional current increase achieved by further increases to the size of the nMOS device would be offset completely by a corresponding increase in the parasitic capacitance at the output nodes. As such, this existing cross-coupled level shifter design is incapable of achieving data speeds/performance above this threshold speed at which the increase in current is completely offset by the increased parasitic capacitance, which is at most perhaps around 2 gigabits per second (Gbps).

There are some existing approaches/architectures that enable level shifters to work at higher speeds than 2 Gbps. Such approaches are current-based and do not include the high-gain latch stage. While such approaches may be able to achieve faster speeds than the existing cross-coupled level shifter architecture, they suffer from various technical problems of their own. For instance, due to the large self-loading effect of these architectures, the duty-cycle and delay observed across the Process, Voltage, Temperature (PVT) spread exhibit significant variation and skew the process corners of the various pMOS and nMOS devices. In addition, due to the limited gain, these architectures need multiple gain stages to realize the logic. As such, they require a larger area than the cross-coupled design and are more susceptible to noise due to the low gain.

Embodiments of the disclosed technology relate to an improved cross-coupled-based voltage level shifter and corresponding circuit implementation and method of operation that achieve a faster resolution than the existing cross-coupled level shifter design. More specifically, and as will be described in more detail later in this disclosure, the pull-down nMOS devices of a voltage level shifter according to embodiments of the disclosed technology may be core IC devices that are several orders of magnitude smaller than the pull-down transistors in the existing cross-coupled design. Because these substantially smaller pull-down nMOS devices have a smaller Vt, the effective width needed to trigger the latch action is much smaller than what is needed in the existing cross-coupled design. This enables the improved cross-coupled voltage level shifters disclosed herein to achieve higher currents that, in turn, support a significantly higher target performance than the existing cross-coupled design, thereby providing a technical improvement over the existing design.

Further, improved voltage level shifters according to embodiments of the disclosed technology utilize a strong arm feedback design that reduces the effect of self-loading and further increases operational speed. In particular, dynamic gates are added in parallel with the pMOS devices in the cross-coupled latch of the improved design disclosed herein to provide strong-arm feedback to the pMOS devices that helps to mitigate contention during the initial logic change. This, in turn, reduces the extent to which the nMOS pull-down devices need to be stronger than the pMOS latch devices. As such, the size of the nMOS pull-down devices can be made even smaller for a given input voltage, thereby reducing the parasitic capacitance at the output nodes. Moreover, the size of the pMOS latch devices can be reduced as well (e.g., scaled to half) because a contribution of charging current to the parasitic capacitance is now also being made by the dynamic strong-arm feedback devices. These aspects of the improved cross-coupled voltage level shifter design constitute additional technical improvements over the existing cross-coupled design.

In addition, the dynamic feedback arm—which consumes static current—is turned off when the logic change of the improved voltage level shifter is complete. Thus, a voltage level shifter according to embodiments of the disclosed technology consumes zero static current, which enables it to achieve low current targets such as those associated with DPDM devices that permit multiple concurrent reads and writes. This constitutes yet another technical improvement over existing cross-coupled level shifters.

As previously noted, the existing cross-coupled level shifter design described above suffers from the technical problem of being unable to achieve high target speeds as a result of the pull-down device widths that are needed to meet the current demands associated with higher performance, and because after a certain point, the current increases achieved by increasing device width are completely offset by corresponding increases in parasitic capacitance at the output nodes of the level shifter. Improved cross-coupled voltage level shifters according to embodiments of the disclosed technology provide a technical solution to this technical problem by substantially reducing the pull-down device widths needed to produce a target current capable of achieving a target performance as well as by reducing the parasitic capacitance generated at any given target current. In addition, voltage level shifters according to embodiments of the disclosed technology are able to achieve this substantially improved performance while still employing the cross-coupled design, and thus, do not suffer from the technical problems associated with the other approaches discussed above that do not use a cross-coupled design.

FIGS. 1A-1C depict an example circuit implementation 100 of an existing cross-coupled level shifter. The circuit 100 may be a step-up level shifter where an input voltage VDD to the circuit 100 that is at a logic high level is lower than an output voltage VDDH that is also at the logic high level. The circuit 100 includes first and second pull-down nMOS devices MN0 and MN1, which may be nMOS field-effect transistors (n-MOSFETs). The nMOS transistors may be 35 A thick-gate input/output (I/O) devices in order to support higher voltage operation. The circuit 100 further includes a cross-coupled latch formed by pMOS devices (e.g., p-MOSFETs) MP0 and MP1. When an input voltage VDD supplied to the level shifter is at a logic low level (i.e., IN=0), input voltage INN supplied to a gate of MN1 is at a logic high level (i.e., INN=1) and input voltage INP supplied to a gate of MN0 is at the logic low level (i.e., INP=0), due to the operation of inverters 106, 108, respectively. Since INN=1, the corresponding gate voltage supplied to MN1 is sufficient to overcome a threshold voltage Vt of MN1, and MN1 turns ON (also referred to herein as activation). Conversely, because IN=0, MN0 is OFF. Moreover, MP0 is ON due to MN1 being ON, and similarly, MP1 is OFF due to MN0 being OFF.

As a result of MP0 being ON and MP1 being OFF, a drain side node of MP0 (i.e., outb_int) is at the logic high level and a drain side node of MP1 (i.e., intermediate node voltage out_int) is at the logic low level. The intermediate node voltage out_int is inverted by inverter 102 to produce output voltage OUTB, while the intermediate node voltage outb_int is inverted by inverter 104 to produce output voltage OUT. Thus, when the input voltage VDD is at the logic low level, the output voltage from the circuit 100 may also be at the logic low level (i.e., OUT=0 and OUTB=1).

Then, when the input voltage VDD transitions from the logic low level to the logic high level (i.e., IN changes from 0 to 1), INP also changes from the logic low level to the logic high level, which results in a gate voltage supplied to MN0 that is sufficient to overcome a Vt of MN0 and turn MN0 ON. Because MP0 is also ON and because MN0 is made stronger than MP0 by design, outb_int at a drain side of MP0 begins to discharge. Once it has discharged by at least a Vt of MP1 (i.e., VDDH-Vt), then MP1 turns ON, thereby triggering the latch action. In particular, the drain side node out_int of MP1 pulls down on the source of MP1, resulting in outb_int going to the logic low level 0 and out_int charging to the logic high level 1. The latch action then maintains outb_int at logic low level 0 and out_int at logic high level 1 until the logic level of the input voltage VDD changes again.

Because outb_int is inverted to obtain output signal OUT=1, when the input voltage VDD is at the logic high level, the level shifter 100 converts VDD to the output voltage VDDH at the logic high level. As noted, circuit 100 may implement a step-up level shifter such that VDD at the logic high level is lower than VDDH at the logic high level. Then, if IN goes from 0 to 1, the other hand of the latch action is triggered, intermediate node out_int goes to 0 and intermediate node outb_int goes to 1, and as a result, OUTB=1 and OUT=0. Thus, for an input voltage VDD that is at the logic low level, the latch action of the level shifter maintains the output voltage VDDH at the logic low level as well.

As discussed earlier with respect to the existing cross-coupled level shifter design generally, the pull-down nMOS transistors of the level shifter 100 (MN0 and MN1) need to be larger in width than the pMOS latch transistors (MP0 and MP1) in order to satisfy the higher current requirements of the nMOS transistors. More specifically, the size of the pMOS transistors (MP0 and MP1) is determined based on the parasitic capacitance on intermediate nodes outb_int and out_int of the level shifter 100, the overdrive voltage (VDDH-Vt), and the frequency of operation. The size of the nMOS transistors (MN0 and MN1), on the other hand, is determined based on the parasitic capacitance on intermediate nodes outb_int and out_int, the overdrive voltage (VDD-Vt), and the frequency of operation. Because, in the case of a step-up level shifter, VDD is less than VDDH (at least at the logic high level), the overdrive voltage at the nMOS transistors will be less than the overdrive voltage at the pMOS transistors. As such, the nMOS transistors need to be larger than the pMOS transistors in order to overcome the deficiency in the overdrive voltage for the nMOS transistors and ensure that there is enough current through these transistors to trigger the latch action. But, as also noted earlier, as the size of the nMOS transistors increases, so too does the parasitic capacitance at the output nodes of the level shifter 100, until a point is reached at which any further current gains that result from size increases are completely offset by corresponding increases in the parasitic capacitance.

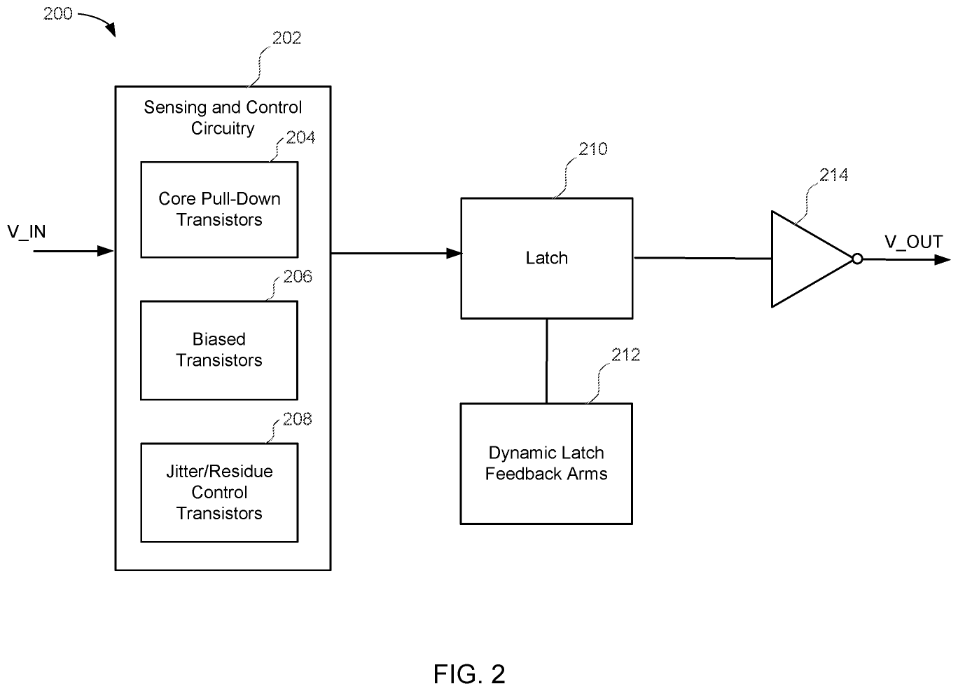

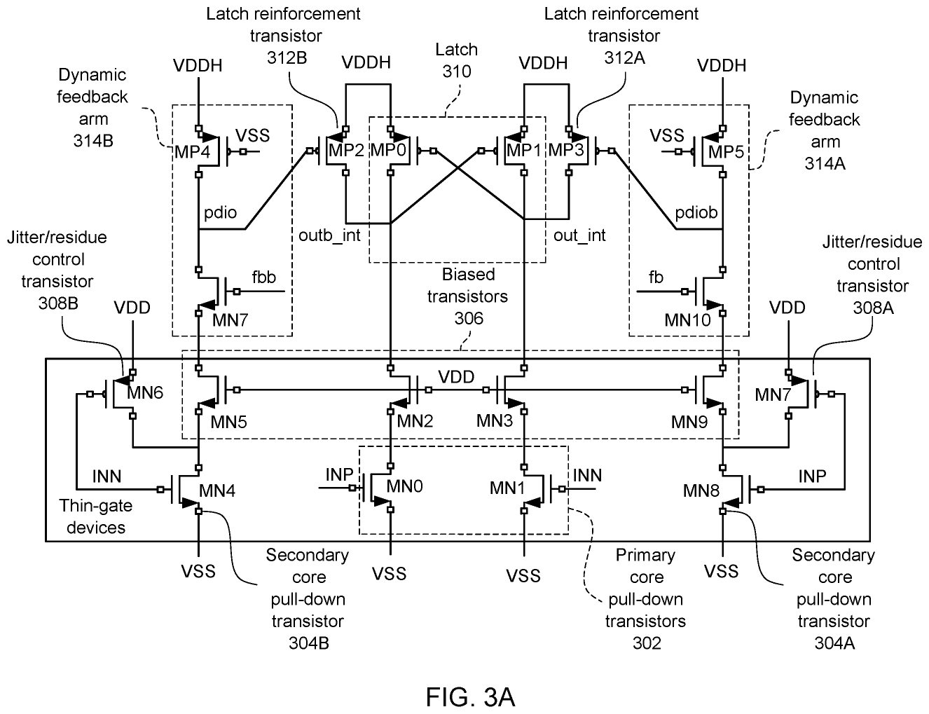

FIG. 2 is a block diagram of a zero static current high-speed voltage level shifter 200 having an improved cross-coupled design according to example embodiments of the disclosed technology. The level shifter 200 is configured to convert input signals having logic voltages in a first voltage domain that are at a logic high level or a logic low level to output signals having logic voltages at corresponding logic high or logic low levels in a second voltage domain. The level shifter 200 may be a step-up level shifter in that at least one of the voltage levels in the first voltage domain may be lower than at least one corresponding voltage level in the second voltage domain. For example, a voltage level corresponding to a logic high level may be lower in the first voltage domain than in the second voltage domain, while the voltage level corresponding to a logic low level in the first voltage domain may be the same as the logic low voltage level in the second voltage domain. For example, the logic low voltage level in each domain may be a ground reference voltage. In some example configurations, however, the ground reference voltages in the different domains may be different despite having the same direct current (DC) voltage, such as by being ground references for different or separate circuits or chips. In alternative example configurations, both the logic high and the logic low voltage levels may be lower in the first voltage domain than in the second voltage domain. In still other example configurations, the logic high voltage levels may be the same, while the logic low voltage level in the first voltage domain is lower than the logic low voltage level in the second voltage domain. Various configurations of logic voltage levels between the first and second voltage domains are possible for the level shifter 200.

The improved cross-coupled level shifter 200 according to embodiments of the disclosed technology includes sensing and control circuitry 202 that, in turn, includes core pull-down transistors 204, biased transistors 206, and jitter/residue control transistors 208. The sensing and control circuitry 202 may receive an input voltage V_IN. The input voltage V_IN may be at a logic high level or a logic low level of a first voltage domain. Gate voltages corresponding to a logic level of the input voltage V_IN or the logic level of the inversion of V_IN may be supplied to various ones of the core pull-down transistors 204 to trigger a corresponding latch action of a latch 210. The latch action that is triggered may correspond to one or the other of two possible latch states—a first latch state in which the latch 210 maintains a voltage on an output node of the voltage level shifter 200 at one of a logic high level or a logic low level and a second latch state in which the latch 210 maintains the voltage at the output node at the other of the logic high level or the logic low level.

In some embodiments, the core pull-down transistors 204 may be core thin-gate IC devices that are substantially smaller in size and may have smaller threshold voltages than the 35A thick-gate nMOS transistors of the existing cross-coupled level shifter 100 depicted in FIGS. 1A-1C. As such, the effective width needed for the core pull-down transistors 204 to trigger the latch action is substantially reduced. The biased transistors 206 may be biased to the input voltage VDD and may be provided to safeguard the thin-gate core pull-down transistors 204 from electrical overstress (EOS), for example. The jitter/residue control transistors 208 may be provided to assist in turning OFF certain ones of the biased transistors 206 to avoid jitter/residue during latch state transitions. In addition, the jitter/residue control transistors 208 may also generally protect the thin-gate devices against stress on the drain-source voltage (Vim) of these devices.

The voltage level shifter 200 may further include dynamic latch feedback arms 212. In some embodiments, each dynamic latch feedback arm 212 may be provided to remove contention of a corresponding pMOS transistor in the latch 210 during the initial logic change and reinforce the latch action associated with that logic change. In some embodiments, each feedback arm 212 may include one or more transistors that are provided in series with a corresponding one or more of the core pull-down transistors 204 and/or the biased transistors 206 and configured to supply a gate voltage to a corresponding latch reinforcement transistor, which itself may be provided in parallel with a corresponding pMOS device of the latch 210. In some embodiments, the dynamic feedback arms 212—which consume static current—may be switched OFF after the logic change is complete to eliminate the consumption of static current and make the level shifter 200 a zero static current device. In some embodiments, the latch reinforcement transistors may form part of the dynamic feedback arms 212, while in other embodiments, the latch reinforcement transistors may be independent from the feedback arms 212.

After the logic change of the latch 210 is complete, the voltage at a particular output node of the voltage level shifter 200 may be logically inverted by inverter 214 to produce output voltage V_OUT. The output voltage V_OUT may be at the same logic level as the input voltage V_IN. In particular, the latch 210 may maintain the output voltage V_OUT at the same logic level as the input voltage V_IN by remaining in a corresponding latch state until a logic level of the input voltage V_IN changes, at which point, the latch 210 may undergo a logic state transition to the other latch state so as to produce an output voltage V_OUT that is at the same logic level as the logic level to which V_IN has changed.

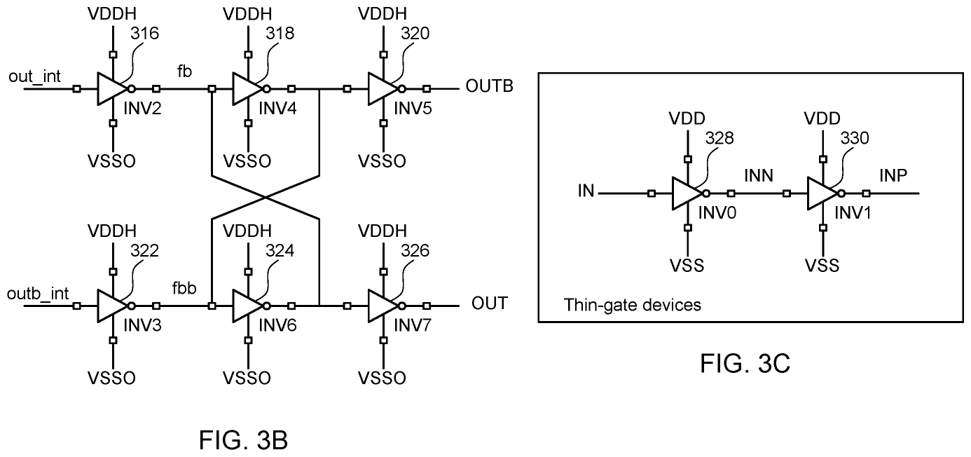

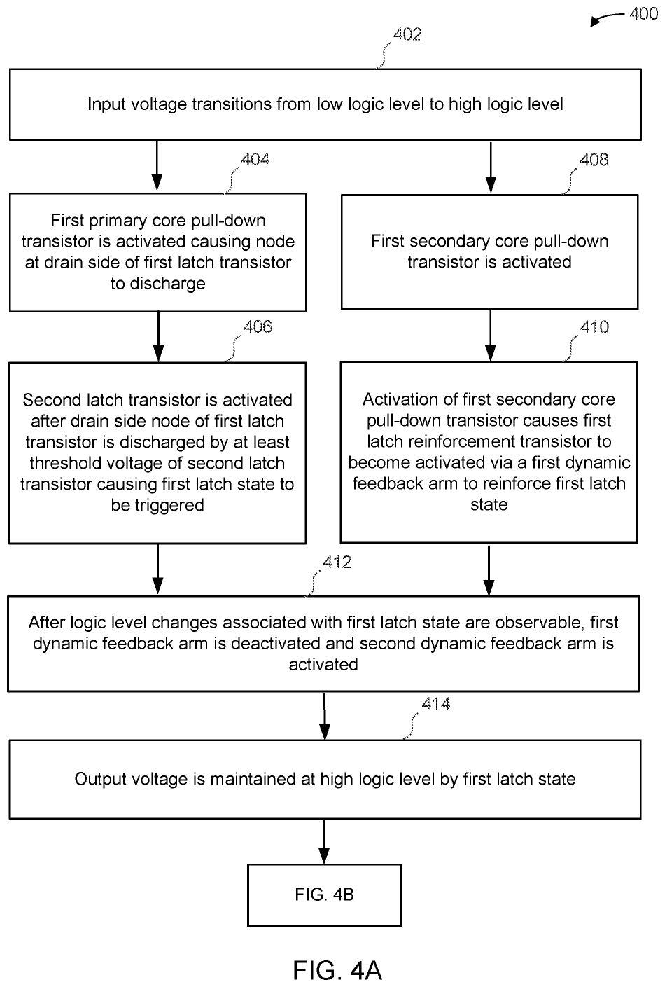

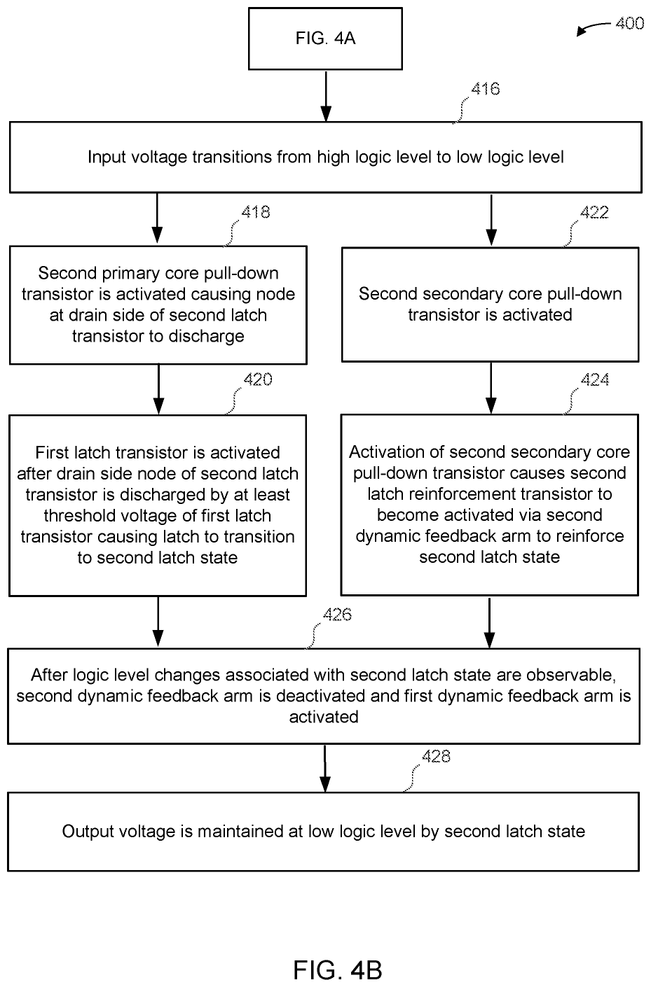

FIGS. 3A, 3B, and 3C depict an example circuit implementation 300 of the zero static current high-speed voltage level shifter 200 according to example embodiments of the disclosed technology. FIGS. 4A and 4B are flowcharts depicting a method of operation 400 of a zero static current high-speed level shifter according to example embodiments of the disclosed technology. The method of operation 400 will be described hereinafter in the context of the example circuit implementation 300 depicted across FIGS. 3A-3C.

Referring first to FIG. 3A, the circuit 300 includes a set of thin-gate devices including primary core pull-down transistors 302, which may be n-channel MOSFETs or another suitable semiconductor device. The primary core pull-down transistors 302 may be referred to hereinafter by the labels MN0 and MN1 shown in FIG. 3A. The set of thin-gate devices further includes secondary pull-down transistors 304A, 304B, which may also be n-channel MOSFETs or another suitable semiconductor device. The secondary pull-down transistors 304A, 304B may be referred to hereinafter by the labels MN8 and MN4, respectively. The primary pull-down transistors MN0 and MN1 and/or the secondary pull-down transistors MN4 and MN8 are an example implementation of the core pull-down transistors 204 of the voltage level shifter 200.

The thin-gate devices of the circuit 300 further include biased transistors 306, which may be n-channel MOSFETs or another suitable semiconductor device. The biased transistors 306 are an example implementation of the biased transistors 206 of the voltage level shifter 200. As noted earlier in connection with the biased transistors 206, the biased transistors 306 may be biased to the input voltage VDD and provided to protect the primary pull-down transistors MN0 and MN1 and/or the secondary pull-down transistors MN4 and MN8 from EOS.

The thin-gate devices of the circuit 300 further include jitter/residue control transistors 308A, 308B, which may be p-channel MOSFETs or another suitable semiconductor device. The jitter/residue control transistors 308A, 308B are an example implementation of the jitter/residue control transistors 208 of the voltage level shifter 200. The jitter/residue control transistors 308A, 308B may be referred to hereinafter by the labels MP7 and MP6, respectively. As noted earlier in connection with the jitter/residue control transistors 208, the jitter/residue control transistors 308A, 308B may be provided to assist in turning OFF certain ones of the biased transistors 306 to avoid jitter/residue during latch state transitions.

More specifically, jitter/residue control transistor MP7 may be provided to reinforce the input voltage VDD and turn OFF transistor MN9 more quickly during a latch state transition that occurs when INP transitions from a logic high level to a logic low level (i.e., INP goes from 1 to 0), and jitter/residue control transistor MP6 may be similarly provided to reinforce the input voltage VDD and turn OFF transistor MN5 more quickly during a latch state transition that occurs when INN transitions from a logic high level to a logic low level (i.e., INN goes from 1 to 0). When MN9 transitions to an OFF state, pdiob is pulled to VDDH, thereby turning off latch reinforcement transistor 312A. Similarly, when MN5 transitions to an OFF state, pdio is pulled to VDDH, thereby turning off latch reinforcement transistor 312B. Stated another way, MP6 and MP7 assist in respectively recovering pdio and pdiob more quickly and removing any inherent intersymbol interference (ISI), jitter, and/or residue present due to a weak MP4 or MP5, respectively.

The circuit 300 further includes latch 310, dynamic feedback arms 314A, 314B, and latch reinforcement transistors 312A, 312B. The latch 310 may include transistors MP0 and MP1, which may be p-channel MOSFETS or any other suitable type of semiconductor device. Transistors MP0 and MP1 may be cross-coupled as shown, with a drain of MP0 connected to a gate of MP1 and a drain of MP1 connected to a gate of MP0. Latch reinforcement transistor 312A (which may be referred to hereinafter by the label MP3) may be provided to reinforce the latch action with respect MP0. Similarly, latch reinforcement transistor 312B (which may be referred to hereinafter by the label MP2) may be provided to reinforce the latch action with respect to MP1.

Dynamic feedback arm 314A—which includes an nMOS transistor (MN10) in series with a pMOS transistor (MP5)—is provided in parallel with MP1 via a connection to the gate of MP3 to provide strong-arm feedback that helps to mitigate resistance of MP0 to the initial logic change. The dynamic feedback arm 314B—which includes an nMOS transistor (MN7) in series with a pMOS transistor (MP4)—is similarly provided in parallel with MP0 via a connection to the gate of MP2 to provide strong-arm feedback that helps to mitigate resistance of MP1 to the initial logic change. As previously noted, the contention reduction assistance provided by the dynamic feedback arms 314A, 314B reduces the extent to which the nMOS pull-down devices (e.g., primary core pull-down transistors MN0 and MN1) need to be stronger than the pMOS latch devices (e.g., MP0 and MP1). As such, the size of the nMOS pull-down devices can be made even smaller for a given input voltage, thereby reducing the parasitic capacitance at intermediate nodes outb_int and out_int.

Referring now to FIG. 4A, method 400 begins at block 402 with an input voltage VDD to the circuit 300 transitioning from a logic low level to a logic high level. Prior to this transition, the input voltage VDD is at the logic low level, i.e., as shown in FIG. 3C, IN=0. The input voltage VDD at the logic low level is logically inverted by inverter 328 to generate a voltage at the logic high level (i.e., INN=1), and this is again logically inverted by inverter 330 to generate a voltage at the logic low level (i.e., INP=0). As a result of INP=0 and INN=1, primary core pull-down nMOS transistors MN0 and MN1 are OFF and ON, respectively. For similar reasons, secondary core pull-down nMOS transistors MN8 and MN4 are also OFF and ON, respectively. Further, pMOS latch transistor MP0 is ON because when MN1 switches ON, it pulls down on a drain side node of pMOS latch transistor MP1, which results in a gate voltage being applied to MP0 that is sufficient to turn MP0 ON. The other pMOS latch transistor MP1, however, remains OFF.

As a result of MP0 being switched ON and MP1 being OFF, the voltage at intermediate node outb_int is at a logic high level and the voltage at intermediate node out_int is at a logic low level. As shown in FIG. 3B, intermediate node voltage out_int is logically inverted three times by inverters 316, 318, and 320 to obtain output voltage signal OUTB and intermediate node voltage outb_int is logically inverted three times by inverters 322, 324, and 326 to obtain output voltage signal OUT. The output signals OUT and OUTB are complementary signals. When out_int=0, then OUTB=1, which may represent an output voltage at a logic low level when OUTB is an active-low signal, for example. Along similar lines, when outb_int=1, then OUT=0, which also may represent an output voltage at a logic low level when OUT is an active-high signal, for example. As such, in some embodiments, when the input voltage VDD is at a logic low level (i.e., IN=0), the output voltage signal OUT and the output voltage signal OUTB may both be at the logic low level as well if, for example, output signal OUT is an active-high signal and OUTB is an active-low signal. It should be appreciated, however, that the output signal OUT need not be an active-high signal and the output signal OUTB need not be an active-low signal, or vice versa, and that either or both signals may be used depending on the logic. In addition, intermediate node voltage out_int, which is at the logic low level, is inverted by inverter 316 to obtain a logic high level signal fb, which in turn, switches ON transistor MN10 of a first dynamic feedback arm 314A. Along similar lines, intermediate node voltage outb_int, which is at the logic high level, is inverted to obtain a logic low level signal fbb that is supplied to MN7. Thus, MN7 is OFF.

Referring again to FIG. 4A, when the input voltage VDD transitions from a logic low level to a logic high level at block 402 (i.e., IN goes from 0 to 1), two parallel flows that support one another are initiated—a logic stream and a dynamic stream. As part of the logic stream, when the input voltage VDD transitions from a logic 0 to a logic 1, a logic level of the input gate voltage supplied to a first primary core pull-down transistor 302 (MN0) also transitions from the logic low level to the logic high level (i.e., INP goes from 0 to 1), which activates (i.e., switches ON) MN0 at block 404. This, in turn, causes MN0 to pull down on a drain side node of a first latch transistor (MP0), and due to the larger size and current requirement of MN0 in relation to MP0, the drain side node of MP0 begins to discharge. Stated another way, when MN0 is switched ON, the intermediate node outb_int is pulled down because primary core pull-down transistor MN0 and biased transistor MN2 are stronger than first latch transistor MP0 while the second latch transistor MP1 is OFF from the previous cycle. In addition, when the input voltage VDD transitions from the logic low level to the logic high level (i.e., IN goes from 0 to 1), a logic level of the input gate voltage supplied to a second primary core pull-down transistor 302 (MN1) transitions from the logic high level to the logic low level (i.e., INN goes from 1 to 0), which causes MN1 to switch OFF.

At block 406 of the method 400, after the drain side node of the first latch transistor (MP0) discharges by at least a Vt of the second latch transistor (MP1), that is, after the drain side node of MP0 discharges to at least VDDH-Vt, MP1 is switched ON, thereby causing the latch action of the latch 310 to be triggered such that the latch 310 transitions to a first latch state. In particular, after MP1 is switched ON, the drain side node of MP1 charges to a logic high level and the drain side node of MP0 discharges to the logic low level in order to maintain the latch 310 in the first latch state. Because intermediate node voltages out_int and outb_int equal 1 and 0, respectively, the corresponding output voltages OUTB and OUT equal 0 and 1, respectively. Thus, OUTB (which may be an active-low signal) is now at the logic high level and OUT (which may be an active-high signal) is also at the logic high level. As such, the circuit 300 functions to translate an input voltage VDD, which is at a logic high level in a first voltage domain, to an output voltage VDDH that is also at a logic high level in a second voltage domain.

Still referring to FIG. 4A, when the input voltage VDD transitions from a logic low level to a logic high level (i.e., IN goes from 0 to 1), a logic level of the input gate voltage supplied to a first secondary core pull-down transistor 304A (MN8) also transitions from the logic low level to the logic high level (i.e., INP goes from 0 to 1), which activates (i.e., switches ON) MN8, at block 408 of the method 400. In addition, when the input voltage VDD transitions from the logic low level to the logic high level (i.e., IN goes from 0 to 1), a logic level of the input gate voltage supplied to a second secondary core pull-down transistor 304B (MN4) transitions from the logic high level to the logic low level (i.e., INN goes from 1 to 0), which causes MN4 to switch OFF.

At block 410 of the method 400, activation of the first secondary core pull-down transistor 304A (MN8) causes a first latch reinforcement transistor 312A (MP3) to switch ON via the operation of the first dynamic feedback arm 314A. A drain of the first latch reinforcement transistor MP3 is connected to a gate of the first latch transistor MP0 and serves to reinforce the latch action by mitigating the initial contention of MP0 to the logic change of the latch 310 to the first latch state. Operations at blocks 408 and 410 may occur at least partially concurrently with operations at blocks 404 and 406. More specifically, as part of the dynamic stream noted earlier, activation of the first dynamic feedback arm 314A pulls down on node pdiob fairly easily due to transistor MP5 being relatively weak. Then, as pdiob transitions to the logic low level, first latch reinforcement transistor MP3 (which is stronger than second latch transistor MP1) charges intermediate node out_int to VDDH, which corresponds to the logic high level. This path is then turned OFF when the fb signal goes to the logic low level, which indicates successful logic conversion on intermediate nodes out_int and outb_int using inverters 316, 318, 322, and 324. The pdiob signal moves towards 0 (i.e., the logic low level) and recovers back to the logic high level (i.e., VDDH) after logic conversion occurs. This may assist in removing the static current path and easing the logic transition.

Then, at block 412 of the method 400, after the logic level changes associated with the first latch state are observable at intermediate nodes outb_int and out_int, the first dynamic feedback arm 314A is deactivated and a second dynamic feedback arm 314B is activated. In particular, because out_int=1 and outb_int=0 in the first latch state, fb=0 and fbb=1 due to the operations of inverters 316 and 322, respectively. Since fb is supplied to a gate of MN10 and fbb is supplied to a gate of MN7, MN10 is switched OFF and MN7 is switched ON. By switching MN10 OFF, the dynamic feedback arm 314A does not consume static current while the latch 310 is maintained in the first latch state. Further, although MN7 is switched ON, there is no logic change in the latch 310 or current in the now active dynamic feedback arm 314B because corresponding secondary core pull-down transistor MN4 remains OFF. At block 414 of the method 400, the output voltage VDDH of the circuit 300 is maintained at the logic high level (i.e., output signal OUTB=0 and output signal OUT=1) as long as the input voltage VDD is at the logic high level.

Referring now to FIG. 4B, at block 416 of the method 400, the input voltage VDD transitions from the logic high level to the logic low level (i.e., IN goes from 1 to 0). Similar to the input voltage transition from 0 to 1, when the input voltage VDD transitions from 1 to 0 at block 416, two parallel flows that support one another are initiated—a logic stream and a dynamic stream. As part of the logic stream, when the input voltage VDD transitions from a logic 1 to a logic 0, a logic level of the input gate voltage supplied to a second primary core pull-down transistor 302 (MN1) transitions from the logic low level to the logic high level (i.e., INN goes from 0 to 1), which activates (i.e., switches ON) MN1, at block 418 of the method 400. This, in turn, causes MN1 to pull down on a drain side node of the second latch transistor (MP1), and due to the larger size and current requirement of MN1 in relation to MP1, the drain side node of MP1 begins to discharge. In addition, when the input voltage VDD transitions from the logic high level to the logic low level (i.e., IN goes from 1 to 0), a logic level of the input gate voltage supplied to the first primary core pull-down transistor 302 (MN0) transitions from the logic high level to the logic low level (i.e., INP goes from 1 to 0), which causes MN0 to switch OFF. Stated another way, when MN1 is switched ON, the intermediate node out_int is pulled down because primary core pull-down transistor MN1 and biased transistor MN3 are stronger than second latch transistor MP1 while the first latch transistor MP0 is OFF from the previous cycle.

At block 420 of the method 400, after the drain side node of the second latch transistor (MP1) discharges by at least a Vt of the first latch transistor (MP0), that is, after the drain side node of MP1 discharges to at least VDDH-Vt, the first latch transistor MP0 is switched ON, thereby causing an opposing latch action of the latch 310 to be triggered such that the latch 310 transitions to a second latch state. In particular, after MP0 is switched ON, the drain side node of MP0 charges to a logic high level and the drain side node of MP1 discharges to the logic low level in order to maintain the latch 310 in the second latch state. Because now out_int=0 and outb_int=1, the corresponding output voltages OUTB=1 and OUT=0. Thus, OUTB (which may be an active-low signal) is now at the logic low level and OUT (which may be an active-high signal) is also at the logic low level. As such, the circuit 300 functions to translate an input voltage VDD, which is now at a logic low level in a first voltage domain, to an output voltage VDDH that is also at a logic low level in a second voltage domain.

Still referring to FIG. 4B, at block 422 of the method 400, when the input voltage VDD transitions from the logic high level to the logic low level (i.e., IN goes from 1 to 0), a logic level of the input gate voltage supplied to the second secondary core pull-down transistor 304B (MN4) transitions from the logic low level to the logic high level (i.e., INN goes from 0 to 1), which activates (i.e., switches ON) MN4. In addition, when the input voltage VDD transitions from the logic high level to the logic low level (i.e., IN goes from 1 to 0), a logic level of the input gate voltage supplied to the first secondary core pull-down transistor 304A (MN8) transitions from the logic high level to the logic low level (i.e., INP goes from 1 to 0), which causes MN8 to switch OFF.

At block 424 of the method 400, activation of the second secondary core pull-down transistor 304B (MN4) causes a second latch reinforcement transistor 312B (MP2) to switch ON via the operation of the second dynamic feedback arm 314B. A drain of the second latch reinforcement transistor MP2 is connected to a gate of the second latch transistor MP1 and serves to reinforce the latch action by mitigating the initial contention of MP1 to the logic change of the latch 310 to the second latch state. Operations at blocks 422 and 424 may occur at least partially concurrently with operations at blocks 418 and 420. More specifically, as part of the dynamic stream noted earlier, activation of the second dynamic feedback arm 314B pulls down on node pdio fairly easily due to transistor MP4 being relatively weak. Then, as pdio transitions to the logic low level, latch reinforcement transistor MP2 (which is stronger than first latch transistor MP0) charges intermediate node outb_int to VDDH, which corresponds to the logic high level. This path is then turned OFF when the fbb signal goes to the logic low level, which indicates successful logic conversion on intermediate nodes out_int and outb_int using inverters 316, 318, 322, and 324. The pdio signal moves towards 0 (i.e., the logic low level) and recovers back to the logic high level (i.e., VDDH) after logic conversion occurs. This may assist in removing the static current path and easing the logic transition.

Then, at block 426 of the method 400, after the logic level changes associated with the second latch state are observable at intermediate nodes outb_int and out_int, the second dynamic feedback arm 314B is deactivated and the first dynamic feedback arm 314A is activated. In particular, because out_int=0 and outb_int=1 in the second latch state, fb=1 and fbb=0 due to the operations of inverters 316 and 322, respectively. Since fb is supplied to a gate of MN10 and fbb is supplied to a gate of MN7, MN10 is switched ON and MN7 is switched OFF. By switching MN7 OFF, the dynamic feedback arm 314B does not consume static current while the latch 310 is maintained in the second latch state. Further, although MN10 is switched ON, there is no logic change in the latch 310 or current in the now active dynamic feedback arm 314A because corresponding secondary core pull-down transistor MN8 remains OFF. At block 428 of the method 400, the output voltage VDDH of the circuit 300 is maintained at the logic low level (i.e., output signal OUTB=1 and output signal OUT=0) as long as the input voltage VDD is at the logic low level.

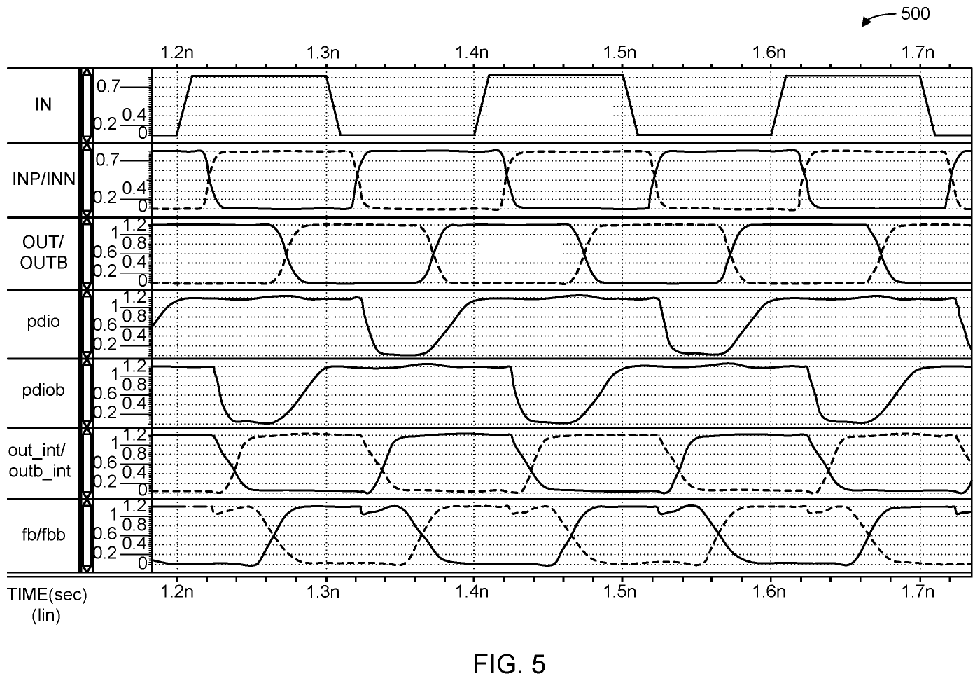

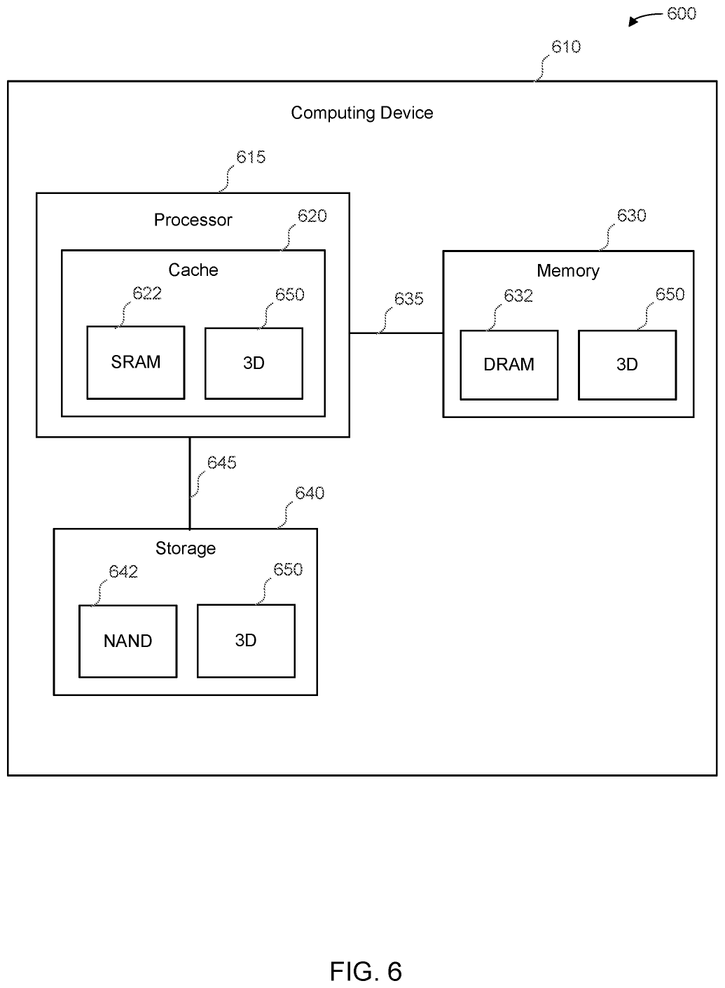

FIG. 5 is a plot 500 of waveforms of various voltage signals over the course of multiple latch state transitions of a voltage level shifter according to example embodiments of the disclosed technology. An input voltage signal IN may be supplied to the voltage level shifter 200, which may have the example circuit implementation 300 depicted in FIG. 3A. The input voltage signal IN may oscillate between a logic high level (e.g., 0.7V) and a logic low level (e.g., 0V). Voltage signals INP and INN may be complementary signals. As previously noted, voltage signal INN may be obtained by inverting the input voltage signal IN, and the voltage signal INP may be obtained by inverting the voltage signal INN. Thus, when the input voltage signal IN is at a logic high level, the voltage signal INN is at a logic low level, while the voltage signal INP is at a logic high level. This is illustrated in FIG. 5. Further, as previously noted, the voltage signal INN may be supplied to primary core pull-down transistor MN1 and secondary core pull-down transistor MN4, while the voltage signal INP may be supplied to primary core pull-down transistor MN0 and secondary core pull-down transistor MN8.

FIG. 5 additionally depicts waveforms for voltages observed at outb_int and out_int as well as waveforms for output voltage signals OUT and OUTB. As shown in FIG. 5, when the input voltage IN transitions to the logic high level, the output signal OUT also subsequently transitions to the logic high level, while the complementary output voltage signal OUTB transitions to the logic low level. Moreover, the output voltage signal OUT transitions from the logic high level to the logic low level and complementary voltage output signal OUTB transitions from the logic low level to the logic high level responsive to transition of the input voltage signal IN from the logic high level to the logic low level. Further, because the output voltage signals OUT and OUTB are obtained by inverting the intermediate node voltages outb_int and out_int, respectively, outb_int transitions from a logic high level to a logic low level and out_int transitions from the logic low level to the logic high level when the input voltage signal transitions from the logic low level to the logic high level.

In addition, as previously described, transition of the input voltage IN from the logic low level to the logic high level results in activation of the first dynamic feedback arm 314A, which in turn, causes pdiob to move towards the logic low level, as shown in FIG. 5. Then, responsive to the fb signal going to the logic low level, which results in the first dynamic feedback arm 314A being deactivated, the pdiob signal recovers back to the logic high level. As depicted in FIG. 5, the recovery of the pdiob signal to the logic high level occurs more slowly than the initial discharge of the pdiob node upon activation of the first dynamic feedback arm 314A.

Along similar lines, transition of the input voltage IN from the logic high level to the logic low level results in activation of the second dynamic feedback arm 314B, which in turn, causes pdio to move towards the logic low level, as shown in FIG. 5. Then, responsive to the fbb signal going to the logic low level, which results in the second dynamic feedback arm 314B being deactivated, the pdio signal recovers back to the logic high level. As depicted in FIG. 5, the recovery of the pdio signal to the logic high level occurs more slowly than the initial discharge of the pdio node upon activation of the second dynamic feedback arm 314B. Further, as shown in FIG. 5, the fb and fbb signals exhibit periodic disturbances while at the logic high level due to coupling from inverters 316 and 322 caused by the sizes of their respective pMOS and nMOS transistors being skewed to give preference to the logic stream. This ensures that the dynamic feedback arms 314A, 314B are deactivated only after the corresponding logic conversion is complete.

FIG. 6 depicts a system 600 comprising three-dimensional memory 650. The system 600 may include one or more voltage level shifters according to embodiments of the disclosed technology. The voltage level shifter(s) may be provided to perform voltage domain translation between any two components or instances of components depicted in FIG. 5. In the depicted embodiment, the system includes a computing device 610. In various embodiments, a computing device 610 may refer to any electronic device capable of computing by performing arithmetic or logical operations on electronic data. For example, a computing device 610 may be a server, a workstation, a desktop computer, a laptop computer, a tablet, a smartphone, a control system for another electronic device, a network attached storage device, a block device on a storage area network, a router, a network switch, or the like. In certain embodiments, a computing device 610 may include a non-transitory, computer readable storage medium that stores computer readable instructions configured to cause the computing device 610 to perform steps of one or more of the methods disclosed herein.

In the depicted embodiment, the computing device 610 includes a processor 615, a memory 630, and storage 640. In various embodiments, a processor 615 may refer to any electronic element that carries out the arithmetic or logical operations performed by the computing device 610. For example, in one embodiment, the processor 615 may be a general-purpose processor that executes stored program code. In another embodiment, a processor 615 may be a field-programmable gate array (FPGA), an application-specific integrated circuit (ASIC), or the like, that operates on data stored by the memory 630 and/or the storage 640. In a certain embodiment, a processor 615 may be a controller for a storage device (e.g., on a storage area network), a networking device, or the like.

In the depicted embodiment, the processor 615 includes a cache 620. In various embodiments, a cache 620 may store data for use by the processor 615. In certain embodiments, a cache 620 may be smaller and faster than the memory 630, and may duplicate data in frequently-used locations of the memory 630, or the like. In certain embodiments, a processor 615 may include a plurality of caches 620. In various embodiments, a cache 620 may include one or more types of memory media for storing data, such as static random access memory (SRAM) 622, three-dimensional memory 650, or the like. For example, in one embodiment, a cache 620 may include SRAM 622. In another embodiment, a cache 620 may include three-dimensional memory 650. In a certain embodiment, a cache 620 may include a combination of SRAM 622, three-dimensional memory 650, and/or other memory media types.

The memory 630, in one embodiment, is coupled to the processor 615 by a memory bus 635. In certain embodiments, the memory 630 may store data that is directly addressable by the processor 615. In various embodiments, a memory 630 may include one or more types of memory media for storing data, such as dynamic random access memory (DRAM) 632, three-dimensional memory 650, or the like. For example, in one embodiment, a memory 630 may include DRAM 632. In another embodiment, a memory 630 may include three-dimensional memory 650. In a certain embodiment, a memory 630 may include a combination of DRAM 632, three-dimensional memory 650, and/or other memory media types.

The storage 640, in one embodiment, is coupled to the processor 615 by a storage bus 645. In certain embodiments, the storage bus 645 may be a peripheral bus of the computing device 610, such as a peripheral component interconnect express (PCI Express or PCIe) bus, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In various embodiments, the storage 640 may store data that is not directly addressable by the processor 615, but that may be accessed via one or more storage controllers. In certain embodiments, the storage 640 may be larger than the memory 630. In various embodiments, a storage 640 may include one or more types of storage media for storing data, such as a hard disk drive, NAND flash memory 642, three-dimensional memory 650, or the like. For example, in one embodiment, a storage 640 may include NAND flash memory 642. In another embodiment, a storage 640 may include three-dimensional memory 650. In a certain embodiment, a storage 640 may include a combination of NAND flash memory 642, three-dimensional memory 650, and/or other storage media types.

In various embodiments, three-dimensional memory 650 may be used to store data in a cache 620, memory 630, storage 640, and/or another component that stores data. For example, in the depicted embodiment, the computing device 610 includes three-dimensional memory 650 in the cache 620, memory 630, and storage 640. In another embodiment, a computing device 610 may use three-dimensional memory 650 for memory 630, and may use other types of memory or storage media for cache 620 or storage 640. Conversely, in another embodiment, a computing device 610 may use three-dimensional memory 650 for storage 640, and may use other types of memory media for cache 620 and memory 630. Additionally, some types of computing device 610 may include memory 630 without storage 640 (e.g., in a microcontroller) if the memory 630 is non-volatile, may include memory 630 without a cache 620 for specialized processors 615, or the like. Various combinations of cache 620, memory 630, and/or storage 640, and uses of three-dimensional memory 650 for cache 620, memory 630, storage 640, and/or other applications will be clear in view of this disclosure.

In various embodiments, the three-dimensional memory 650 may include one or more chips, packages, die, or other integrated circuit devices comprising three-dimensional memory arrays with multiple layers of memory cells, disposed on one or more printed circuit boards, storage housings, and/or other mechanical and/or electrical support structures. For example, one or more dual inline memory modules (DIMMs), one or more expansion cards and/or daughter cards, a solid-state-drive (SSD) or other storage device, and/or another memory and/or storage form factor may comprise the three-dimensional memory 650. The three-dimensional memory 650 may be integrated with and/or mounted on a motherboard of the computing device 610, installed in a port and/or slot of the computing device 610, installed on a different computing device 610 and/or a dedicated storage appliance on a network, in communication with a computing device 610 over an external bus, or the like.

The three-dimensional memory 650, in various embodiments, may include one or more memory dies. A memory die may include multiple layers of memory cells in a three-dimensional memory array. In various embodiments, three-dimensional memory may include magnetoresistive RAM (MRAM), phase change memory (PCM), resistive RAM (ReRAM), NOR Flash memory, NAND Flash memory, Silicon-Oxide-Nitride-Oxide-Silicon (SONOS) memory, or the like.

In certain embodiments, the three-dimensional memory 650 may include a plurality of planar memory cells forming a three-dimensional array, a plurality of word lines extending horizontally across the layers (e.g., in-plane), and a plurality of selector columns or pillars extending vertically through the plurality of layers. In further embodiments, the selector columns or pillars may be coupled to the memory cells, and may include central conductors surrounded by one or more concentric selective layers. In various embodiments, one or more selective layers may permit an electrical current through a cell, between a word line and a central conductor, in response to a voltage satisfying a threshold. In certain embodiments, a selector column or pillar that extends through a plurality of layers of planar memory cells may facilitate reading to or writing from individual memory cells by limiting leakage current through other cells. Additionally, in further embodiments, forming a selector pillar or column that extends through a plurality of layers may simplify manufacturing compared to forming selector devices in individual layers alternating with memory cell layers.

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “circuit,” “module,” “apparatus,” or “system.” Furthermore, aspects of the present disclosure may take the form of a computer program product embodied in one or more non-transitory computer readable storage media storing computer readable and/or executable program code.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like.

Modules may also be implemented at least partially in software for execution by various types of processors. An identified module of executable code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code may include a single instruction, or many instructions, and may even be distributed over several different code segments, among different programs, across several memory devices, or the like. Where a module or portions of a module are implemented in software, the software portions may be stored on one or more computer readable and/or executable storage media. Any combination of one or more computer readable storage media may be utilized. A computer readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

1. A voltage level shifter, comprising:
a cross-coupled latch comprising a first latch transistor and a second latch transistor, wherein a drain of the first latch transistor is connected to a gate of the second latch transistor and a drain of the second latch transistor is connected to a gate of the first latch transistor;
a first pull-down transistor and a second pull-down transistor, wherein a drain of the first pull-down transistor is connected to the drain of the first latch transistor and a drain of the second pull-down transistor is connected to the drain of the second latch transistor;
a first latch reinforcement transistor and a second latch reinforcement transistor, wherein a drain of the first latch reinforcement transistor is connected to the gate of the first latch transistor and a drain of the second latch reinforcement transistor is connected to the gate of the second latch transistor;
a first dynamic feedback arm and a second dynamic feedback arm, wherein the first dynamic feedback arm drives the first latch reinforcement transistor and the second dynamic feedback arm drives the second latch reinforcement transistor;
a first one or more inverters connected to a drain side node of the second latch transistor, the first one or more inverters comprising an output connected to the first dynamic feedback arm;
a second one or more inverters connected to a drain side node of the first latch transistor, the second one or more inverters comprising an output connected to the second dynamic feedback arm; and
a plurality of biased transistors including a first biased transistor connected to the drain of the first latch transistor and the drain of the first pull-down transistor, a second biased transistor connected to the drain of the second latch transistor and the drain of the second pull-down transistor, a third biased transistor connected to the second dynamic feedback arm, and a fourth biased transistor connected to the first dynamic feedback arm, wherein gates of the first, second, third, and fourth biased transistors are connected to each other.

2. The voltage level shifter of claim 1, wherein:
responsive to activation, the first pull-down transistor is configured to pull down on the drain side node of the first latch transistor to initiate a transition of the cross-coupled latch to a first latch state; and
responsive to activation, the second pull-down transistor is configured to pull down on the drain side node of the second latch transistor to initiate a transition of the cross-coupled latch from the first latch state to a second latch state.

3. The voltage level shifter of claim 2, wherein the first pull-down transistor has a higher current requirement than the first latch transistor and the second pull-down transistor has a higher current requirement than the second latch transistor.

4. The voltage level shifter of claim 2, wherein:
the first pull-down transistor is activated responsive to an input voltage to the voltage level shifter transitioning from a logic low voltage level in a first voltage domain to a logic high voltage level in the first voltage domain, and
the second pull-down transistor is activated responsive to the input voltage transitioning from the logic high voltage level in the first voltage domain to the logic low voltage level in the first voltage domain.

5. The voltage level shifter of claim 4, wherein the cross-coupled latch transitions to the first latch state upon activation of the second latch transistor.

6. The voltage level shifter of claim 5, wherein the second latch transistor is activated responsive to the drain side node of the first latch transistor discharging by at least a threshold voltage of the second latch transistor.

7. The voltage level shifter of claim 5, wherein, when the latch is in the first latch state, a voltage of a first output node corresponding to the drain side node of the second latch transistor is maintained at a logic high voltage level in a second voltage domain and a voltage of a second output node corresponding to the drain side node of the first latch transistor is maintained at a logic low level in the second voltage domain.

8. The voltage level shifter of claim 7, wherein:
the first one or more inverters are configured to logically invert the voltage of the first output node to generate an active-low output voltage signal that is at the logic high voltage level of the second voltage domain when the latch is in the first latch state; and
the second one or more inverters are configured to logically invert the voltage of the second output node to generate an active-high output voltage signal that is at the logic high voltage level of the second voltage domain when the latch is in the first latch state.

9. The voltage level shifter of claim 8, wherein, when the latch is in the second latch state, the voltage of the first output node is maintained at the logic low voltage level in the second voltage domain and the voltage of the second output node is maintained at the logic high level in the second voltage domain.

10. The voltage level shifter of claim 9, wherein, when the latch is in the second latch state, the first one or more inverters are configured to logically invert the voltage of the first output node to generate an active-low output voltage signal that is at the logic low voltage level of the second voltage domain and the second one or more inverters are configured to logically invert the voltage of the second output node to generate an active-high output voltage signal that is at the logic low voltage level of the second voltage domain.

11. The voltage level shifter of claim 4, wherein the cross-coupled latch transitions to the second latch state upon activation of the first latch transistor, wherein the first latch transistor is activated responsive to the drain side node of the second latch transistor discharging by at least a threshold voltage of the first latch transistor.

12. The voltage level shifter of claim 2, wherein the first pull-down transistor and the second pull-down transistor are primary pull-down transistors, further comprising:
a first secondary pull-down transistor and a second secondary pull-down transistor, wherein the first secondary pull-down transistor is activated responsive to an input voltage to the voltage level shifter transitioning from a logic low voltage level in a first voltage domain to a logic high voltage level in the first voltage domain and the second secondary pull-down transistor is activated responsive to the input voltage to the voltage level shifter transitioning from the logic high voltage level in the first voltage domain to the logic low voltage level in the first voltage domain.

13. The voltage level shifter of claim 12, wherein activation of the first secondary pull-down transistor causes the first latch reinforcement transistor to become activated via activation of the first dynamic feedback arm, and wherein upon activation the first latch reinforcement transistor reinforces a latch action of the second latch transistor in the first latch state.

14. The voltage level shifter of claim 13, wherein the first dynamic feedback arm is deactivated responsive to logic level changes being sensed at output nodes of the voltage level shifter, and wherein deactivation of the first dynamic feedback arm ceases static current consumption while the latch is in the first latch state.

15. The voltage level shifter of claim 12, wherein activation of the second secondary pull-down transistor causes the second latch reinforcement transistor to become activated via activation of the second dynamic feedback arm, and wherein upon activation the second latch reinforcement transistor reinforces a latch action of the first latch transistor in the second latch state.

16. A method, comprising:
activating control circuitry of a voltage level shifter responsive to a transition of an input voltage to the voltage level shifter from a logic low level in a first voltage domain to a logic high level in the first voltage domain, wherein activating the control circuitry causes a latch of the voltage level shifter to initiate a transition to a first latch state;
activating feedback circuitry of the voltage level shifter to reinforce the first latch state of the latch, wherein activating feedback circuitry is based on outputs from one or more inverters connected to an output node of the voltage level shifter;
maintaining an output voltage of an output node of the voltage level shifter at a logic high level in a second voltage domain while the input voltage is at the logic high level in the first voltage domain; and
protecting the latch of the voltage level shifter from electrical overstress based on a plurality of biased transistors connected to the latch and feedback circuitry, wherein gates of the plurality of biased transistors are connected to each other.

17. The method of claim 16, wherein activating the feedback circuitry of the voltage level shifter to reinforce the first latch state of the latch comprises activating a first dynamic feedback arm of the voltage level shifter to cause a latch reinforcement transistor to become activated, wherein the latch reinforcement transistor is configured to reinforce the first latch state.

18. The method of claim 17, further comprising:
detecting logic level changes at output nodes of the voltage level shifter; and
deactivating the first feedback arm responsive to detecting the logic level changes.

19. The method of claim 18, wherein deactivation of the first dynamic feedback arm ceases static current consumption while the latch is in the first latch state.

20. An integrated circuit, comprising:
core circuitry configured to operate at voltages in a first voltage domain; and
a voltage level shifter configured to translate input voltage signals received from the core circuitry at one or more logic voltage levels in the first voltage domain to output voltage signals at one or more corresponding logic voltage levels in a second voltage domain, the voltage level shifter comprising:
a latch for maintaining an output voltage of the voltage level shifter at a same logic voltage level in the second voltage domain as a logic voltage level of an input voltage to the voltage level shifter;
control circuitry for initiating a logic state transition of the latch responsive to a change in the logic voltage level of the input voltage to the voltage level shifter;
feedback circuitry to reinforce the logic state transition of the latch;
one or more inverters connected an output node of the latch, the first one or more inverters comprising an output connect to the feedback circuitry; and
a plurality of biased transistors connected to the latch and the feedback circuitry, wherein gates of the plurality of biased transistors are connected to each other.

21. The voltage level shifter of claim 1, wherein the first one or more inverters comprises:
a first inverter having a first input connected to a drain side node of the first second latch transistor and a first output connected to the first dynamic feedback arm;
a second inverter having a second input connected to the first output of the first inverter and a second output; and
a third inverter having a third input connected to the second output of the second inverter and a third output.

22. (canceled)

23. The voltage level shifter of claim 12, wherein a drain of the first secondary pull-down transistor is connected to a source of the third biased transistor and a drain of the second secondary pull-down transistor is connected to a source of the fourth biased transistor, the voltage level shifter further comprising:
a first control transistor and a second control transistor, wherein a drain of the first control transistor is connected to the source of the third biased transistor and to a drain of the first secondary pull-down transistor, wherein a gate of the first control transistor is connected to a gate of the first secondary pull-down transistor, wherein a drain of the second control transistor is connected to the source of the fourth biased transistor and to a drain of the second secondary pull-down transistor, wherein a gate of the second control transistor is connected to a gate of the second secondary pull-down transistor.
